(19) United States
(12) Patent Application Publication
(10) Pub. No.: US 2008/0108164 A1
(43) Pub. Date: May 8, 2008

(54) Sensor System and Method

(76) Inventor: Vladislav A. Oleynik, Pittsboro, NC (US)

Correspondence Address: MORRISON & FOERSTER LLP, 425 MARKET STREET, SAN FRANCISCO, CA, 94105-2482, US

(21) Appl. No.: 11/740,421

(22) Filed: Apr. 26, 2007

Related U.S. Application Data
(63) Continuation of application No. 11/738,795, filed on Apr. 23, 2007.
Application No. 11/738,795 is a continuation-in-part of application No. 11/557,022, filed on Nov. 6, 2006, now abandoned.

(51) Int. Cl. H01L 21/00

(52) U.S. Cl. 438/49

(57) ABSTRACT

A sensor system and method for detecting the presence of one or more target substances reacting with one or more target recognition element types for producing an electrical charge detectable by a differential pair of field effect transistors that provide increased sensitivity by minimizing common mode effects on the differential pair. The differential pair is controlled by optimization algorithms in a digital signal processor that reads and store electrical characteristics of the differential pair and maintains the differential pair at optimal operating points based on continuously monitoring the differential pair. One or more target recognition element types are disbursed over a sensor gate area of the differential pair that detects one or more signature signals created by the binding of one or more target substances and the target recognition element types. The detected signature signals are compared with a library of stored signature signals for determining the identity of the target substances.

This application is a Continuation of U.S. patent application Ser. No. 11/738,795 filed on Apr. 23, 2007 and incorporated by reference herein and a Continuation-in-Part (CIP) of U.S. patent application Ser. No. 11/557,022 filed on Nov. 6, 2006 and incorporated by reference herein, No. 11/533,111 filed on Sep. 19, 2006 and incorporated by reference herein, and No. 11/462,972 filed on Aug. 7, 2006 and incorporated by reference herein.

### BACKGROUND

The present invention relates generally to sensors for detecting the presence of biological and biochemical target substances, and more particularly to sensors that rely on reactions between biological and biochemical target substances and target recognition element types disbursed over a sensing surface to produce an electrical charge detectable by electronic means. It relies on a combination of semiconductor integrated circuitry in combination with digital signal processing techniques to optimize the detection process and negate the undesirable effects of environmental and electrical noise and other perturbations that produce errors and decrease sensitivity.

Sensors, particularly biochemical sensors, have application in fields such as medical diagnostics, industrial safety, environmental monitoring and bioterror prevention for detection, identification and quantification of diseases, infectious agents, and toxic elements. They are also useful for detection, identification and quantification of biochemical elements that are beneficial to the human population and the environment. They may generally be used for detection of various biochemical substances such as viruses, bacteria, spores, allergens and other toxins. Biochemical sensors may also be useful for medical diagnostics for detecting diseases such as avian influenza and Human Immunodeficiency Virus (HIV-1)) infection. Whether found in medical laboratories or in industrial complexes for monitoring ambient air quality, sensors must be capable of rapid detection and identification of biochemical substances as well as notification to those responsible for such activities.

A major limitation of existing sensors and biochemical sensors, particularly when used in a field environment, is the detection sensitivity that is limited by various external factors. Detection sensitivity is an important sensor parameter that determines a minimum detectable level of particular biochemical target substances, as well as provides greater distinction among biochemical target substances. These factors may include external noise from various sources, temperature variations, electromagnetic radiation, power source perturbations, humidity, exposure to cosmic radiation and other environmental distortions. These factors degrade the signal-to-noise ratio of most biochemical sensors, which lowers detection sensitivity. Some of these factors may also cause an operating point of the sensor circuitry to drift from an optimal value, which can also lower detection sensitivity.

### SUMMARY

The present invention provides a means for detecting the presence of one or more biochemical target substances, such as toxins, pathogens, nucleic acids, proteins, viruses, bacteria, spores, allergens, toxins and enzymes. It is capable of providing a high level of detection sensitivity through the use of an integrated differential pair of field effect transistors having a common substrate and common source, collocated in close proximity on a common silicon substrate. The common substrate also includes a temperature sensor and heating element. The common substrate, common source, temperature sensor and heating element are controlled by a digital signal processor for optimizing performance, including detection sensitivity. The use of a differential pair of field effect transistors reduces the effects of common mode perturbations to the differential pair.

An embodiment of the of the invention is a sensor system for detecting one or more target substances, comprising one or more target recognition element types disbursed over a sensor gate area of a differential pair of field effect transistors for sensing an electrical charge created when the one or more target recognition element types react with the one or more target types. The sensed electrical charge modulates a sensor channel of the differential pair field effect transistors to provide a differential output signal signature in which the differential pair of field effect transistors comprises a sensor field effect transistor and a reference field effect transistor having a common substrate connection and a common source connection controlled by a digital signal processor. A reference gate area of the reference field effect transistor is isolated from the effects of the sensed electrical charge created on the sensor gate area, the digital signal processor for monitoring parameters of the differential pair, executing optimization algorithms, and controlling the operating characteristics to provide a differential output signal signature of the differential pair based on the optimization algorithms. The digital signal processor measures, processes, identifies and stores a differential output signal signature from the differential pair of field effect transistor when a reaction of the one or more target recognition element types with the one or more target types is sensed by the sensor gate area. There is a means for notifying a user of the detection. Detection can be continuous, instantaneous and occur in real-time.

The invention comprises a sensor system for detecting one or more target substances, comprising: one or more target recognition element types disbursed over a sensor gate area of a differential pair of field effect transistors. A digital signal processor monitors parameters of the differential pair of field effect transistors and controls operating characteristics of the differential pair of field effect transistors to an optimum operating range for signal sensing. The differential pair of field effect transistors senses an electrical charge created by a reaction between the one or more target recognition element types and the one or more target substances in proximity of the sensor gate area, and provides a responsive output signal. The digital signal processor measures, processes, identifies and stores the responsive output signal signature, and notifies a user of an identifying result.

A specific target recognition element of the sensor system may react with one or more specific target types, that is, a first target recognition element type may react with a first target type. The sensor system may further comprise an operating structure of the differential pair of field effect transistors selected from the group consisting of p-channel enhancement mode, p-channel depletion mode, n-channel enhancement mode, and n-channel depletion mode. In the sensor system, the differential pair of field effect transistors may be fabricated on a common silicon substrate in close proximity to one another for minimizing differences in environmental and electrical influences between both field effect transistors in the differential pair. In the sensor system, the digital signal processor may control the operating characteristics of the differential pair by controlling a common substrate voltage, a common source current, and a quiescent drain voltage of the reference field effect transistor based on the optimization algorithms. The sensor system may further comprise a temperature sensor and a heating means fabricated on a single silicon substrate with the differential pair of field effect transistors. The digital signal processor of the sensor system may read the temperature sensor signal and control the temperature of the single silicon substrate by controlling a signal to the heating means. The temperature sensor and heating means of the sensor system controlled by the digital signal processor may be used for self-cleaning the sensor gate area, for preparing the sensor gate area for disbursement of one or more target recognition element types, and for maintaining a stable temperature during normal sensing operations. A single target recognition element type of the sensor system disbursed over the sensor gate area may react with only a single target type for producing a unique time-varying, signature output signal from the sensor field effect transistor and reference field effect transistor of the differential pair. The time-varying signature output signal comprises an amplitude and a plurality of frequencies. The digital signal processor of the sensor system may include a memory having a plurality of stored signature output signals for comparing with the measured signature output signal and identifying the single target type. A first target recognition element type of the sensor system disbursed over the sensor gate area may react with only a first target type and a second target recognition element type disbursed over the sensor gate area may react with only a second target type for producing a unique time-varying, superimposed first and second signature output signal from the sensor field effect transistor and reference field effect transistor of the differential pair. The digital signal processor of the sensor system may include a memory having a plurality of stored signature output signals for comparing the stored signature signals with the measured superimposed first and second signature output signal and identifying the first and second target type.

The recognition element may be a protein, nucleic acid, inorganic molecule or and organic molecule. The recognition element may also be an antibody, antibody fragment, oligonucleotide, DNA, RNA, aptamer, enzyme, cell fragment, receptor, bacteria, bacterial fragment, virus or viral fragment. The target substance may be a molecule, compound, complex, nucleic acid, protein, virus, bacteria, bacterial fragment, cell or cell fragment. The target substance may be a protein, nucleic acid, inorganic molecule or and organic molecule.

Another embodiment of the present invention includes a method of using a sensor array comprising two or more sensor systems described above. The method of using the sensor array may comprise two or more sensor systems for detecting the presence of two or more target types. The sensor array and method may comprise a first sensor system for detecting the presence of a first target type and a second sensor system for detecting the presence of a second target type.

Yet another embodiment of the present invention is a sensor method for detecting the presence of one or more target types, comprising the steps of disbursing one or more target recognition element types over a sensor gate area of a differential pair of field effect transistors for sensing an electrical charge created when the one or more target recognition element types react with the one or more target types, the sensed electrical charge modulating a sensor channel of the differential pair field effect transistors, controlling a common substrate connection and a common source connection of the differential pair of field effect transistors comprising a sensor field effect transistor and a reference field effect transistor by a digital signal processor, wherein a reference gate area of the reference field effect transistor is isolated from the effects of the sensed electrical charge created on the sensor gate area, determining characteristics of the differential pair, executing optimization algorithms, and controlling the operating characteristics of the differential pair based on the optimization algorithms by the digital signal processor, measuring, processing, identifying and storing a differential output signal signature from a sensor field effect transistor and a reference field effect transistor of the differential pair by the digital signal processor when a reaction of the one or more target recognition element types with the one or more target types is sensed by the sensor gate area, and notifying a user of the detection. The disbursing step may comprise disbursing a specific target recognition element over a sensor gate area of a differential pair of field effect transistors for sensing an electrical charge created when the one or more target recognition element types react with the one or more target types, the sensed electrical charge modulating a sensor channel of the differential pair field effect transistors. The sensor method may further comprise selecting an operating structure of the differential pair of field effect transistors from the group consisting of p-channel enhancement mode, p-channel depletion mode, n-channel enhancement mode, and n-channel depletion mode. The sensor method may further comprise fabricating the differential pair of field effect transistors on a common silicon substrate in close proximity to one another for minimizing differences in environmental and electrical influences between both field effect transistors in the differential pair. The controlling step may further comprise controlling the operating characteristics of the differential pair by controlling a common substrate voltage, a common source current, and a quiescent drain voltage of the reference field effect transistor based on the optimization algorithms. The sensor method may further comprise fabricating a temperature sensor and a heating means on a single silicon substrate with the differential pair of field effect transistors controlled by the digital signal processor. The sensor method may further comprise reading the temperature sensor signal and controlling the temperature of the single silicon substrate by controlling a signal to the heating means by the digital signal processor. The sensor method may further comprise self-cleaning the sensor gate area, preparing the sensor gate area for disbursement of one or more target recognition element types, and maintaining a stable temperature during normal sensing operations by controlling the temperature sensor and heating means by the digital signal processor. The disbursing step may comprise disbursing a single target recognition element over a sensor gate area of a differential pair of field effect transistors for sensing an electrical charge created when the target recognition element reacts with the one or more target types, the sensed electrical charge modulating a sensor channel of the differential pair field effect transistors producing a unique time-varying signature output signal from the sensor field effect transistor and reference field effect transistor of the differential pair. The sensor method may further comprise storing a plurality of signature output signals in a digital signal processor memory for comparing with the measured signature output signal and identifying the single target type. The disbursing step may include disbursing a first target recognition element type over the sensor gate area that reacts with only a first target type and disbursing a second target recognition element type over the sensor gate area that reacts with only a second target type for producing a unique time-varying, superimposed first and second signature output signal from the sensor field effect transistor and reference field effect transistor of the differential pair. The time-varying signature output signal comprises an amplitude and a plurality of frequencies. The digital signal processor used in the sensor method may include a memory having a plurality of stored signature output signals for comparing with the measured superimposed first and second signature output signal and identifying the first and second target type.

The sensor system and method further comprises using the heating means to heat the sensor gate area to a temperature of between about 35° Celsius and about 80° Celsius to self-clean the sensor gate to allow for reuse of the sensor system. The digital signal processor automatically controls the parameters of the heating means for the self-cleaning of the sensor gate and sensor surface process.

In another aspect, a sensor method for forming an array comprises assembling an array of two or more sensors according to the method described above. The sensor method may comprise assembling an array of two or more sensors for detecting the presence of two or more target types. The sensor method may comprise assembling a first sensor system for detecting the presence of a first target type and a second sensor system for detecting the presence of a second target type.

### BRIEF DESCRIPTION OF THE DRAWINGS

These and other features, aspects and advantages of the present invention will become better understood with regard to the following description and accompanying drawings wherein:

FIG. 1A depicts a diagram of a single target recognition element disbursed over a sensor gate area and a multitude of targets and target types;

FIG. 1B depicts a diagram of a single target recognition element disbursed over a gate area binding with a target substance in the presence of a multitude of target types;

FIG. 1C depicts a diagram of a plurality of target recognition element types disbursed over a gate area binding with a plurality of target substances in the presence of a multitude of target types;

FIGS. 2A-2J depict side views of processing steps for fabricating a differential pair of field effect transistors on a silicon substrate;

FIG. 3 depicts a top view of a dual fabricated differential pair of field effect transistors on a silicon substrate;

FIG. 4 depicts an electrical equivalent circuit of a packaged dual fabricated differential pair of field effect transistors on a silicon substrate;

FIG. 5A depicts a conceptual relationship between analog differential pair sensor circuits and a digital signal processor;

FIG. 5B depicts a simplified diagram of a sensor system including a differential pair of field effect transistors, two current sources, a digital signal processor and associated circuitry;

FIG. 5C depicts a detailed diagram of a sensor system including a differential pair of field effect transistors, two current sources, a digital signal processor and associated circuitry;

FIGS. 6A-6C depict the steps of a sensor optimization algorithm executing in a digital signal processor for automatically controlling the operating characteristics of the differential pair of field effect transistors as shown in FIGS. 5A and 5B;

FIG. 7A depicts typical plotted parametric data obtained from a differential pair of p-channel depletion mode field effect transistors by a digital signal processor where FIG. 7A represents data collected in step 656 and stored in step 658 of FIG. 6B;

FIG. 7B depicts typical plotted parametric data obtained from a differential pair of n-channel depletion mode field effect transistors by a digital signal processor FIG. 7B represents data collected in step 656 and stored in step 658 of FIG. 6B;

FIG. 7C depicts an optimization method using the plotted parametric data of FIG. 7A, shown as a reference transistor;

FIG. 7D depicts an optimization method using the plotted data of FIG. 7C, shown without chemistry applied, after chemistry and biology are applied, and after an environmental change in acidity (Ph);

FIG. 8 depicts process steps for implementing an operational embodiment of the present invention; and

FIGS. 9A-9D show typical responses from a differential pair of field effect transistors with binding and without binding of a target recognition element and a target substance.

FIG. 10A illustrates a two-by-two sensor array in a system configuration where the recognition elements in the array may be selected from one of the embodiments shown herein;

FIG. 10B illustrates a four-by-four sensor array in a system configuration where the recognition elements in the array may be selected from one of the embodiments shown herein.

### DETAILED DESCRIPTION OF THE DRAWINGS

The differential pair field effect sensor and reference elements described below may comprise either p-channel devices or n-channel devices, and may be either depletion mode or enhancement mode devices. Where it is necessary to show a particular device, an arbitrary choice of a p-channel depletion mode is illustrated.

The terms “target”, “target substance” or “target type” mean any material, the presence or absence of which is to be detected and that is capable of interacting with a recognition element. The targets that may be detected include, without limitation, molecules, compounds, complexes, nucleic acids, proteins, such as enzymes and receptors, viruses, bacteria, cells and tissues and components or fragments thereof. As a result, the methods disclosed herein are broadly applicable to many different fields including medical diagnostics, proteomics, genomics, public health, environmental monitoring, drug testing and discovery, biodefense, automated testing and telemedicine. Exemplary targets include, without limitation, biochemical weapons such as anthrax, botulinum toxin, and ricin, environmental toxins, insecticides, aerosol agents, proteins such as enzymes, peptides, and glycoproteins, nucleic acids such as DNA, RNA and oligonucleotides, pathogens such as viruses and bacteria and their components, blood components, drugs, organic and inorganic molecules, sugars, and the like. The target may be naturally occurring or synthetic, organic or inorganic.

The term “recognition element” refers to any chemical, molecule or chemical system that is capable of interacting with a target or target type. Recognition elements can be, for example and without limitation, antibodies, antibody fragments, peptides, proteins, glycoproteins, enzymes, nucleic acids such as oligonucleotides, aptamers, DNA, RNA, organic and inorganic molecules, sugars, polypeptides and other chemicals. A recognition element can also be a thin film that is reactive with a target of interest.

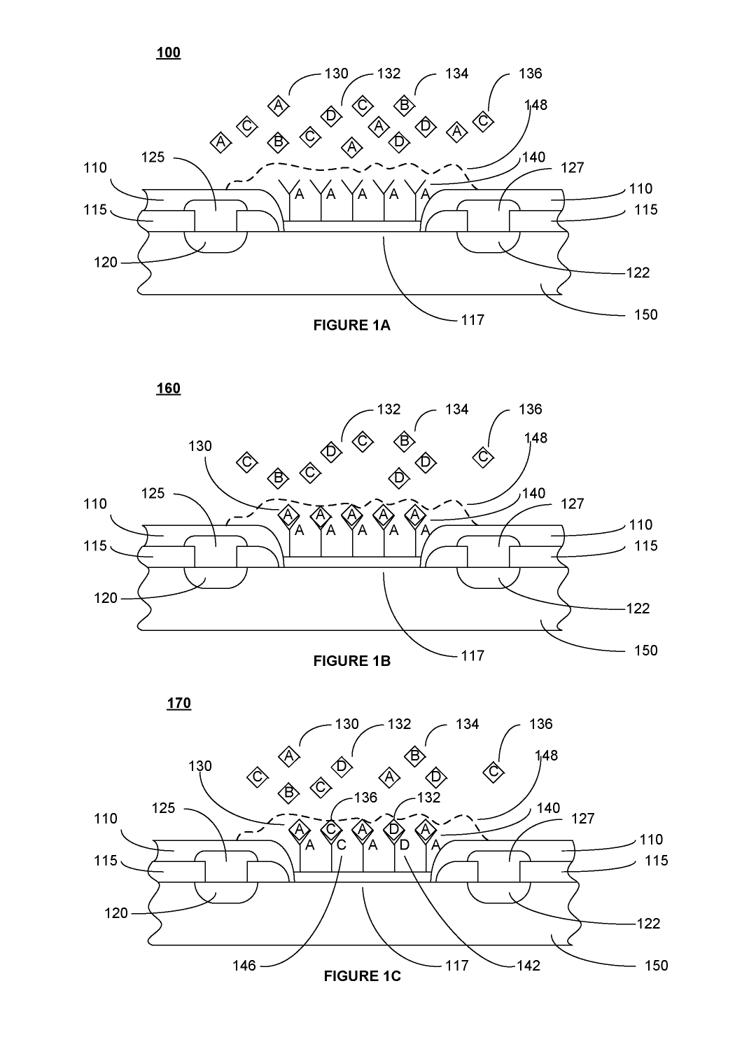

Turning to FIG. 1A, FIG. 1A depicts a diagram 100 of a single target recognition element type 140 disbursed over a sensor gate area 117 of a differential pair field effect sensor element and a multitude of target types 130, 132, 134, 136. The target recognition elements 140 may or may not be encased in a gel 148, which allows target types 130, 132, 134, 136 to pass through and bind with the target recognition elements 140. The field effect sensor element includes a sensor gate area 117 positioned between a source 120 and a drain 122 doped into a silicon base substrate 150. A silicon oxide layer 115 is grown over the substrate 150, drain 120 and source 122. An insulating layer may or may not be deposited over the sensor gate area 117. Metal interconnections 125, 127 connect the drain 120 and source 122 to external terminals of the device. A passivating layer 110 may be applied over the entire device except for the sensor gate area 117.

Turning to FIG. 1B, FIG. 1B depicts a diagram 160 of a single target recognition element 140 disbursed over a sensor gate area 117 binding with a target substance 130 in the presence of a multitude of target types 130, 132, 134, 136. FIG. 1B is the same as FIG. 1A except it shows a single target type 140 that binds with a single target recognition element type 130 to produce a unique signature signal that distinguishes the reaction and differentiates the bound target from other targets.

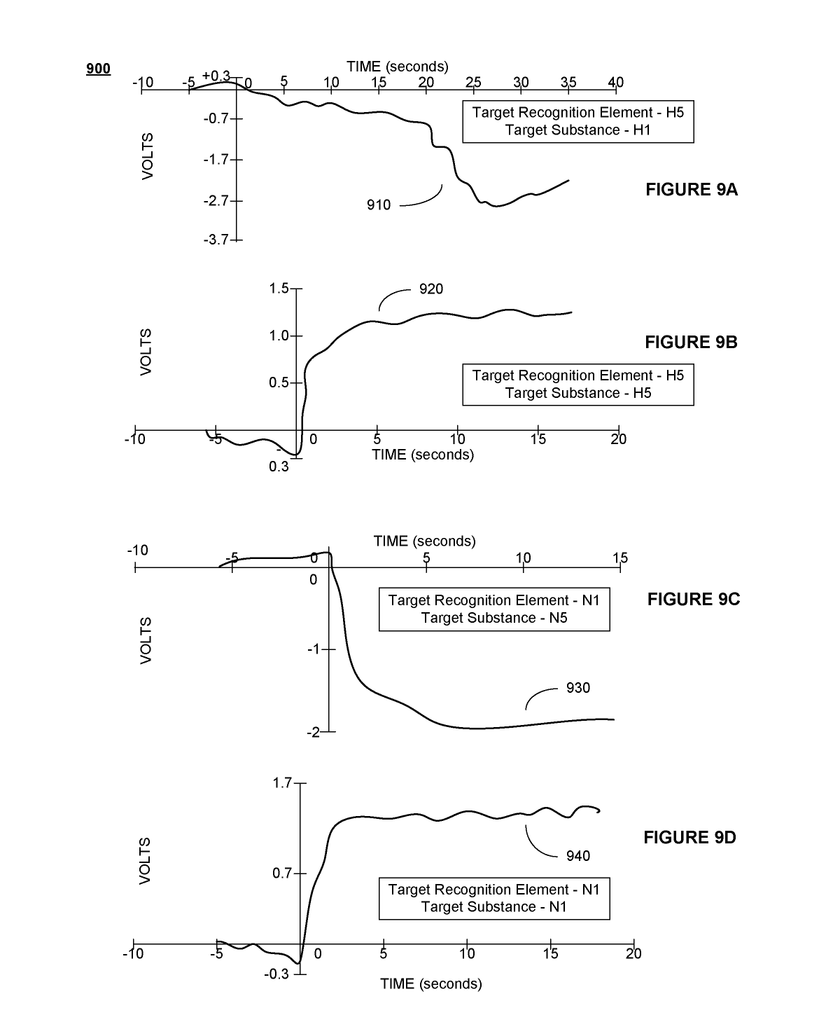

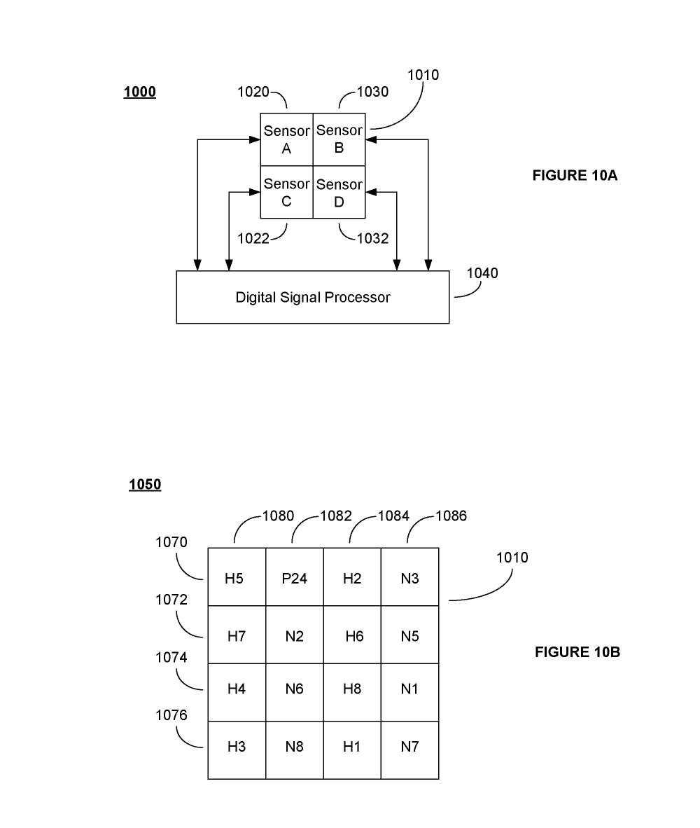

Turning to FIG. 1C, FIG. 1C depicts a diagram 170 of a plurality of target recognition element types 140, 142, 146 disbursed over a gate area 117 binding with a plurality of target types 130, 132, 136 in the presence of a multitude of target types 130, 132, 134, 136. Note that with multiple target recognition types 140, 142, 146, multiple target types 130, 132, 134, 136 may be sensed. For example, the sensor gate element having a coating of H5 and N1 target recognition element types would be capable of sensing the H5N1 avian flu virus. The resultant signature signal output from such a sensor element upon sensing the H5N1 virus would be a superposition of the H5 signature signal shown in FIG. 9B and the N1 signature signal shown in FIG. 9D, which could be easily stored in the pre-stored signature signal library within a digital signal processor or personal computer.

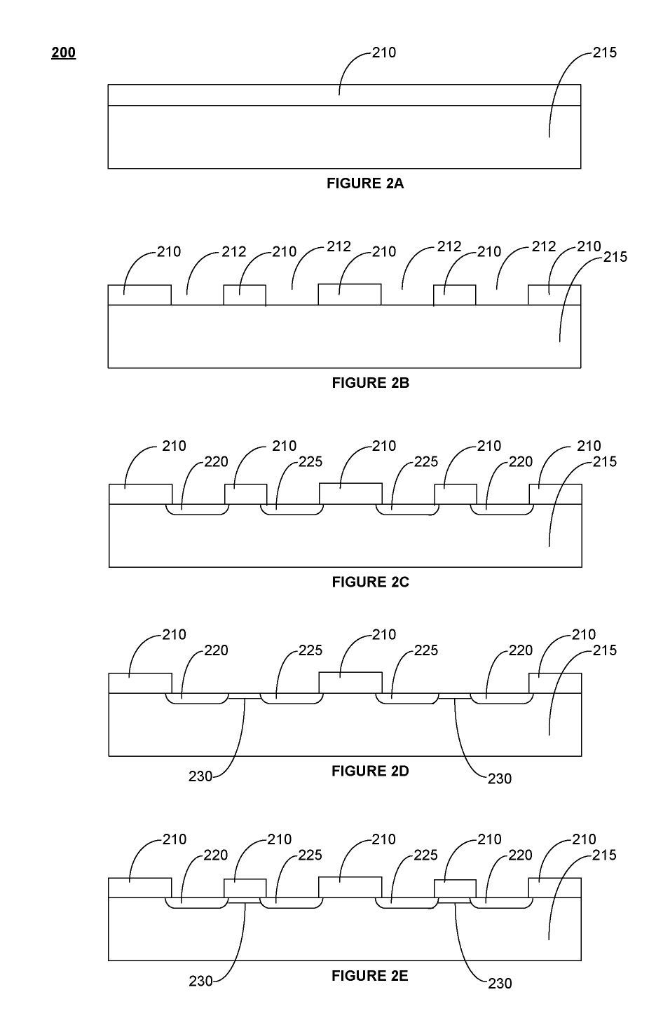

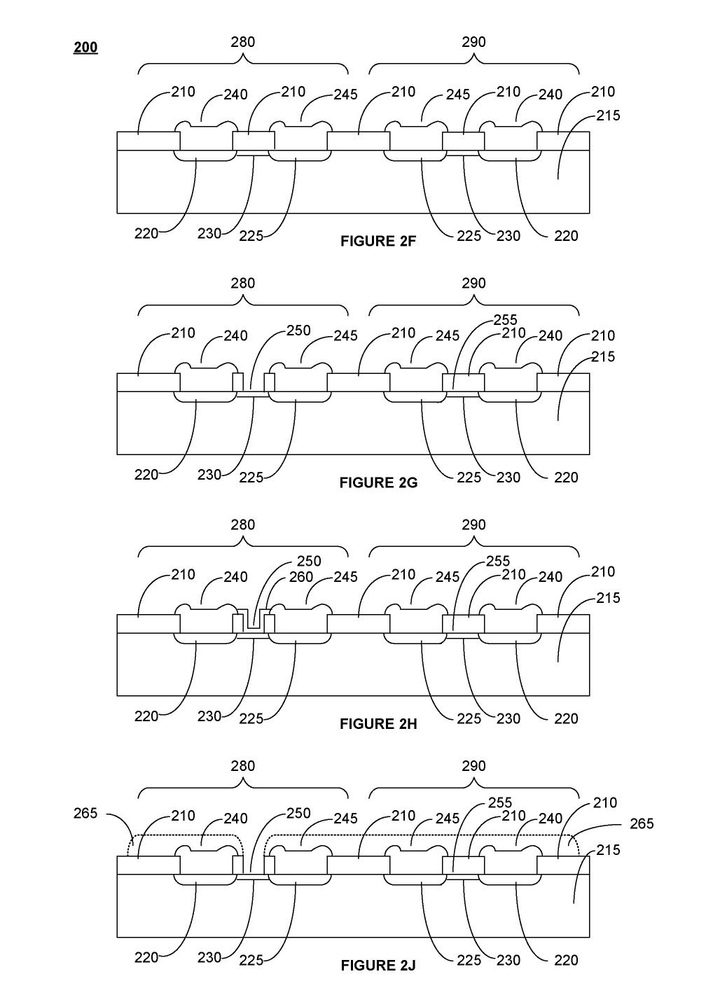

Turning to FIGS. 2A-2J, FIGS. 2A-2J depict side views 200 of processing steps for fabricating a differential pair of field effect transistors on a silicon substrate base 215. FIG. 2A depicts a p-type or an n-type substrate base 215 where a layer of silicon oxide 210 has been grown on the surface of the substrate base 215. FIG. 2B depicts contact openings 212 created in the oxide layer 210 by a common photolithographic/photoresist process used in the semiconductor industry. FIG. 2C depicts an addition of p++ or n++ wells 220, 225 doped into the substrate base 215 to form drain regions 220 and source regions 225. FIG. 2D further depicts removal of certain oxide areas for the creation of channel areas 230 in the substrate base. The channel areas 230 may or may not require additional doping. FIG. 2E depicts re-creation of an oxide covering 210 over the channel area 230, if the channel area creation required removal of an original oxide covering 210. FIG. 2F depicts the addition of a metal interconnection 240 to the drain 220 and a metal interconnection 245 to the source 225 of sensor transistor (this may be the sensor drain) 280 and reference field effect transistor (this may be the reference drain) 290 that comprise the differential pair. FIG. 2G depicts the opening of a gate area 250 by removal of the oxide layer 210 of the sensor from the sensor field effect transistor 280. The oxide layer 210 from the gate area 255 of the reference field effect transistor 290 is left intact. FIG. 2H depicts an option of covering the gate area 250 of the sensor field effect transistor 280 with a protective insulating layer 260. And finally, FIG. 2J depicts completion of the differential pair of a sensor field effect transistor 280 and a reference field effect transistor 290 with a covering the completed structure with a passivating layer 265, except for the gate area 250 of the sensor field effect transistor 280, which is not covered with a passivating layer 265.

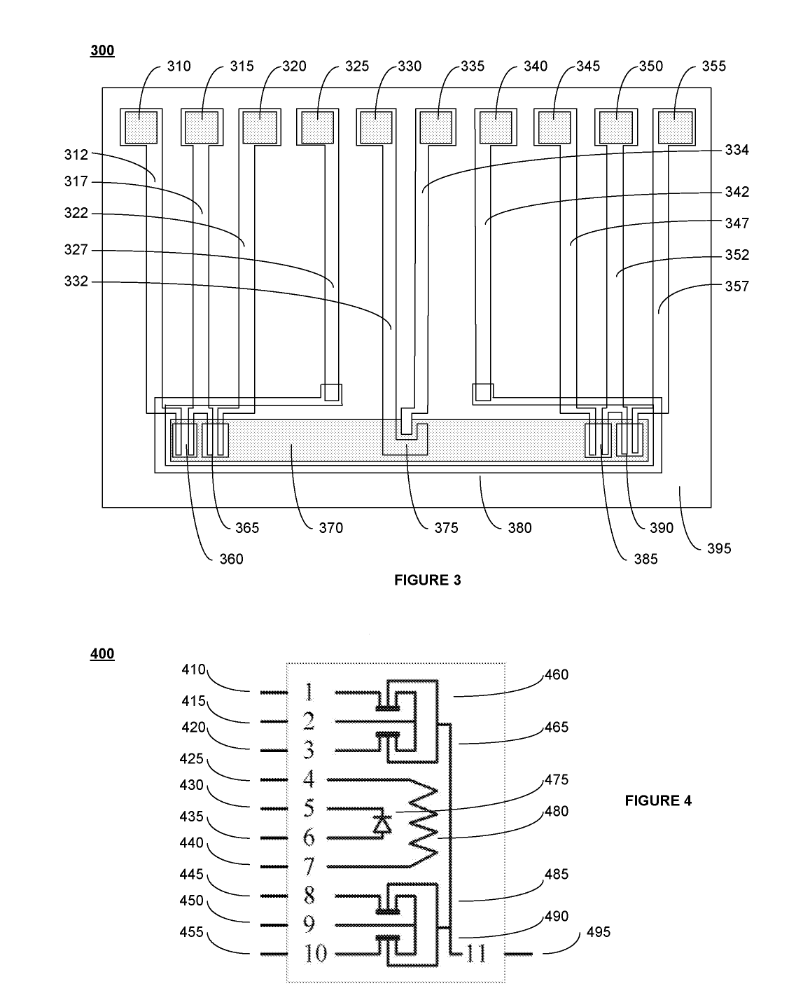

Turning to FIG. 3, FIG. 3 depicts a top view 300 of a first differential pair of field effect transistors 360, 365 and a second pair of field effect transistors 385, 390, all fabricated on a silicon substrate 395. A drain of a sensor field effect transistor 360 of the first differential pair of field effect transistors 360, 365 is interconnected to a wire bonding area 310 by a metallic interconnect 312. The sources of the sensor field effect transistor 360 and reference field effect transistor 365 of the first differential pair of field effect transistors 360, 365 are connected together and interconnected to a common wire bonding area 315 by a metallic interconnect 317. A drain of the reference field effect transistor 365 of the first differential pair of field effect transistors 360, 365 is interconnected to a wire bonding area 320 by a metallic interconnect 322. Similarly, a drain of a sensor field effect transistor 385 of the second differential pair of field effect transistors 385, 390 is interconnected to a wire bonding area 345 by a metallic interconnect 347. The sources of the sensor field effect transistor 385 and reference field effect transistor 390 of the second differential pair of field effect transistors 385, 390 are connected together and interconnected to a common wire bonding area 350 by a metallic interconnect 352. A drain of the reference field effect transistor 390 of the second differential pair of field effect transistors 385, 390 is interconnected to a wire bonding area 355 by a metallic interconnect 357. A heating element 380 embedded in the substrate 395 is connected to wire bonding areas 325, 340 by metallic interconnects 327, 342, respectively. A temperature sensing element 375 embedded in the substrate 395 is connected to wire bonding areas 330, 335 by metallic interconnects 332, 334, respectively. A metallic film deposition 370 is positioned within the boundaries of the heating element 380 and overlays the field effect transistors 360, 365, 385, 390 and the temperature sensing element 375 to provide uniform heat distribution. Note that each differential pair of field effect transistor 360, 365 and 385, 390, are located in close proximity to each other in order to be under the influence of the same common mode environmental conditions, such as temperature, electromagnetic radiation, noise, and other factors such as light, cosmic rays, and the like. Common mode electrical signal effects from such common mode environmental conditions will be canceled out by the common mode rejection capabilities of the field effect differential pair.

Turning to FIG. 4, FIG. 4 depicts an electrical equivalent circuit 400 of a packaged dual fabricated differential pair of field effect transistors 460, 465, 485, 490, heating element 480 and temperature sensing element 475 on a connecting point of the silicon substrate 455. A drain of a reference field effect transistor of a first pair of field effect transistors is connected to a connecting point 410, and a drain of a sensor field effect transistor of a first pair of field effect transistors is connected to a connecting point 420. A common source of the sensor and reference field effect transistors of the first field effect transistor pair is connected to a connecting point 415. A drain of a reference field effect transistor of a second pair of field effect transistors is connected to a connecting point 445, and a drain of a sensor field effect transistor of a second pair of field effect transistors is connected to a connecting point 455. A common source of the sensor and reference field effect transistors of the second field effect transistor pair is connected to a connecting point 450. A base substrate common to the four field effect transistors is connected to a connecting point 495. A heating element is connected to connecting points 425, 440, and a temperature sensing element is connected to connecting points 430, 435.

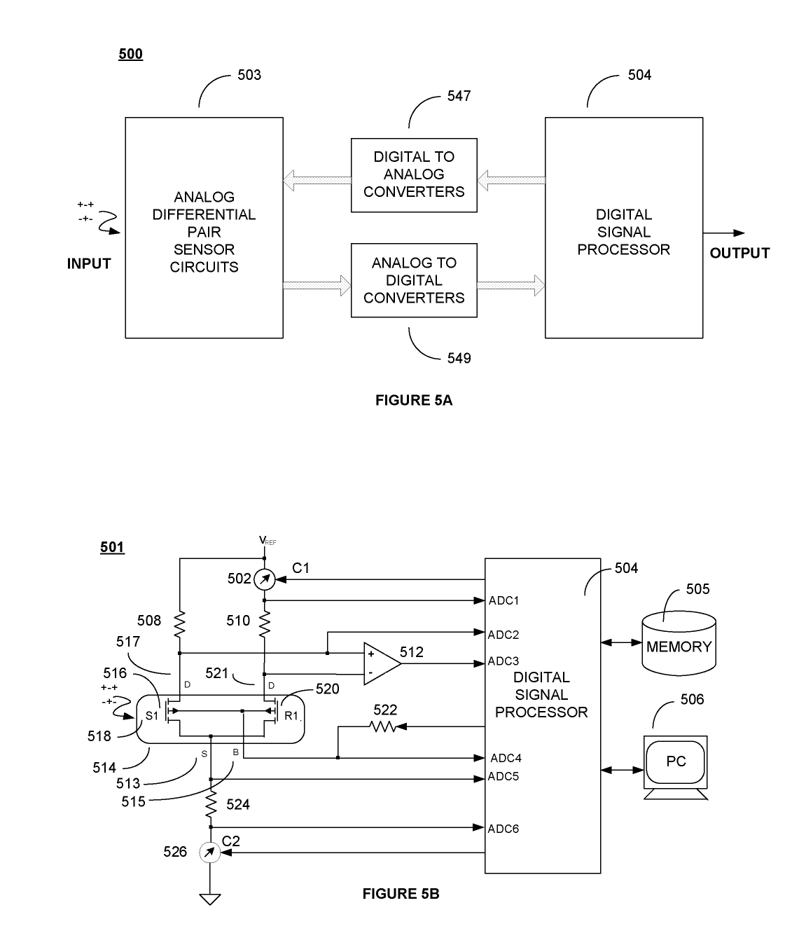

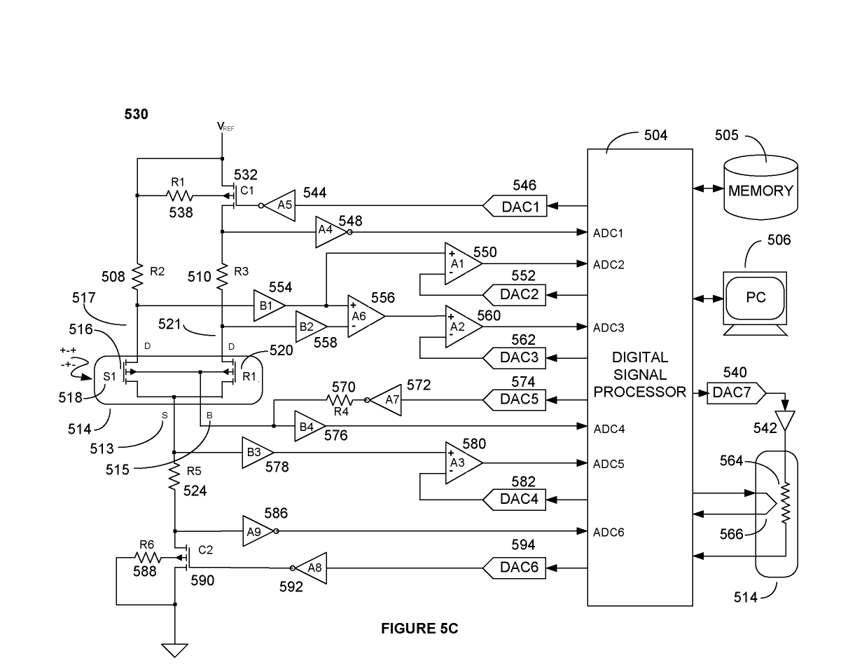

Turning to FIG. 5A, FIG. 5A depicts a conceptual relationship 500 between analog differential pair sensor circuits 503 and a digital signal processor 504. The analog differential pair sensor circuits 503 include analog adjusting circuitry that surrounds the differential pair and comprises current sources and balancing circuitry. The digital signal processor 504 senses the analog parameters of the analog differential pair sensor circuits 503 through the analog to digital converters 549 and determines optimized values for setting the analog values of the current sources and balancing circuitry through the digital to analog converters 547. Other analog to digital converters 549 are used to detect the optimized output signal from the analog differential pair sensor circuits 503 when a reaction between a target recognition element and a target is sensed. These signals are processed by the digital signal processor 504 for identifying the sensed target, which is provided as an output. This configuration represents a unique configuration whereby a digital signal processor is in a feedback loop of an analog circuit for balancing and optimizing the analog circuitry.

Turning to FIG. 5B, FIG. 5B depicts a simplified diagram of a sensor system 501 including a differential pair of field effect transistors 514, two current sources 502, 526, a digital signal processor 504, a personal computer 506 and associated circuitry. The differential pair of field effect transistors 514, comprising a sensor field effect transistor 516 and reference field effect transistor 520, detects reactions at the sensor gate surface 518 between target recognition elements and target substances while providing a means for rejection common mode signals affecting both field effect transistors in the differential pair 514. Detected reactions provide a normal mode signal at the sensor gate surface 518 which is amplified by the differential pair 516, 520, to provide an amplified differential signal at the drains 517, 521 of the differential pair 516, 520. A differential amplifier 512 amplifies and converts the differential drain signals to a normal mode signal, which is sent to the digital signal processor 504 for processing as described below. The output signal at the drain 517 of the sensor field effect transistor 516 is also sent to the digital signal processor 504. Resistors 508, 510 are connected to the drains 571, 521 of the field effect differential pair 516, 520 for providing a source of drain current to the differential pair 516, 520. A common source resistor 524 connected to the common sources 513 of the differential pair 516, 520 enable the differential operation of the differential pair 516, 520. Control of a current source 526 connected to the common source resistor 524 and of a voltage at the common base substrate 515 via resister 522 of the differential pair 516, 520 by the optimization algorithms in the digital signal processor 504, while monitoring the common base substrate voltage 513 and the voltage at the output of the current source 526, enables the optimization algorithms in the digital signal processor 504 to maintain the differential pair 516, 520 in an optimal operating condition by removing distortions that degrade signal sensitivity. The digital signal processor 504 optimization algorithms also keep the differential pair 516, 520 in balance by controlling and monitoring the current source 502 connected to the reference field effect transistor drain 521. A personal computer 506 provides a user interface for control of the digital signal processor 504. The digital signal processor 504 is connected to a memory 505 that includes a plurality of stored signature outputs signals for comparing with the signature output signal generated from a target interaction to identify a target type.

Turning to FIG. 5C, FIG. 5C depicts a detailed diagram of a sensor system 530, including a differential pair of field effect transistors 514, two current sources 532, 590, a digital signal processor 504, a personal computer 506 and associated circuitry. As described above, the differential pair of field effect transistors 514, comprising a sensor field effect transistor 516 and reference field effect transistor 520, detects reactions at the sensor gate surface 518 between target recognition elements and target substances while providing a means for rejection common mode signals affecting both field effect transistors in the differential pair 514. Detected reactions provide a normal mode signal at the sensor gate surface 518 which is amplified by the differential pair 516, 520, to provide an amplified differential signal at the drains 517, 521 of the differential pair 516, 520. After the differential drain signals are buffered by buffer amplifiers 554, 558, a differential amplifier 556 amplifies and converts the differential drain signals to a normal mode signal, which is sent to the digital signal processor 504 via level shifting circuits for processing as described below. Level shifting circuits are controlled by the digital signal processor 504 and are used to maintain a signal with the dynamic range of the analog-to-digital converters within the digital signal processor 504. Level shifting circuits comprising a differential amplifier 550 and a digital-to-analog converter 552 maintain the sensor field effect transistor signal from a buffer amplifier 554 within dynamic range of an analog-to-digital converter within the digital signal processor 504. Level shifting circuits comprising a differential amplifier 560 and a digital-to-analog converter 562 maintain the normal mode drain signal from a differential amplifier 556 within dynamic range of an analog-to-digital converter within the digital signal processor 504. Level shifting circuits comprising a differential amplifier 580 and a digital-to-analog converter 582 maintain the differential pair 564 common source voltage at the output of a buffer amplifier 578 within dynamic range of an analog-to-digital converter within the digital signal processor 504. The output signal at the drain 517 of the sensor field effect transistor 516 is sent to the digital signal processor 504 via a buffer amplifier 554 and level shifting circuitry 550, 552. Resistors 508, 510 are connected to the drains 517, 521 of the field effect differential pair 516, 520 for providing a source of drain current to the differential pair 516, 520. A common source resistor 524 connected to the common sources 513 of the differential pair 516, 520 enable the differential operation of the differential pair 516, 520. The optimization algorithms in the digital signal processor 504 control a current source 590, 588 connected to the common source resistor 524 via a digital-to-analog converter 594 and amplifier 592, and control a voltage at the common base substrate 515 of the differential pair 516, 520 via a digital-to-analog converter 574, amplifier 572 and resistor 570. The algorithms also monitor the common base substrate voltage via a buffer amplifier 576 and the voltage at the output of the current source 590, 588 via an amplifier 586. These control and monitoring functions by the digital signal processor optimization algorithms enable the digital signal processor 504 to maintain the differential pair 516, 520 in an optimal operating condition and remove distortions that degrade signal sensitivity. The optimization algorithms in the digital signal processor 504 also keep the differential pair 516, 520 in balance by controlling a current source 532, 538 via a digital-to-analog converter 546 and amplifier 544, and by monitoring, via an amplifier 548, the current source 532, 538 connected to the reference field effect transistor drain 521. A personal computer 506 provides a user interface for control of the digital signal processor 544. The digital signal processor 504 is connected to a memory 505 that includes a plurality of stored signature outputs signals for comparing with the signature output signal generated from a target interaction to identify a target type.

The detailed sensor system 530 shown in FIG. 5C enables the digital signal processor 504 using optimization algorithms to compensate the field effect differential pair 514 for continuously changing environmental factors by altering the operating point on the voltage-current characteristics of the differential pair 514. The control of the differential pair 514 is achieved by two current sources 532, 590 and the base substrate voltage that performs the role of a common gate for all devices on the substrate. The control scheme requires that a change in any one parameter of channel resistance, differential pair balance or average drain voltage requires an adjustment of the other two.

The detailed diagram of FIG. 5C also includes controlling the temperature operating characteristic using a heating element 564 embedded in the substrate containing the differential pair 514 via a digital-to-analog converter 540 and amplifier 542. Also included in the substrate is a temperature sensing element 566 connected to the digital signal processor 504 for controlling the substrate temperature. A conventional proportional control algorithm may be used in the digital signal processor 504 for maintaining the substrate at a desired temperature. The temperature of the substrate may be used to maintain a temperature most favorable for reactions between target recognition elements and targets. This temperature may be different for different target recognition elements and different targets, but is generally between 28° and 35° Celsius in order to obtain reactions within a reasonably short sampling time of several minutes. The temperature may also be controlled for sensor self-cleaning and for target recognition element deposition on the sensor gate area 518. For self cleaning the sensor surface, the heating element is used to heat the sensor surface from between about 35° Celsius and about 80° Celsius.

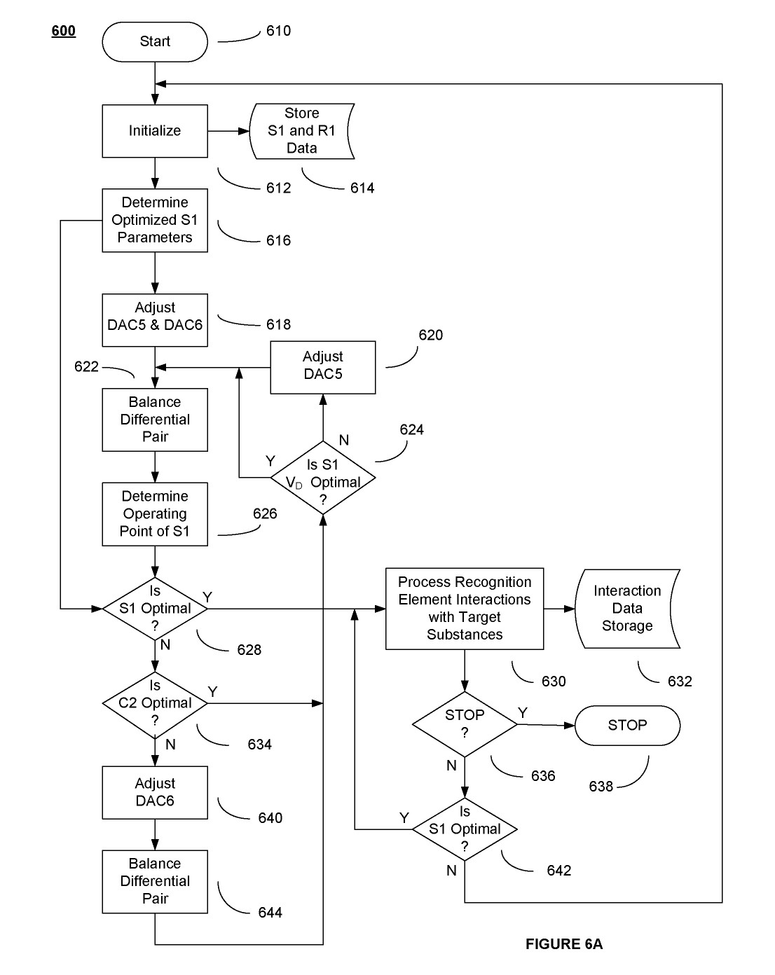

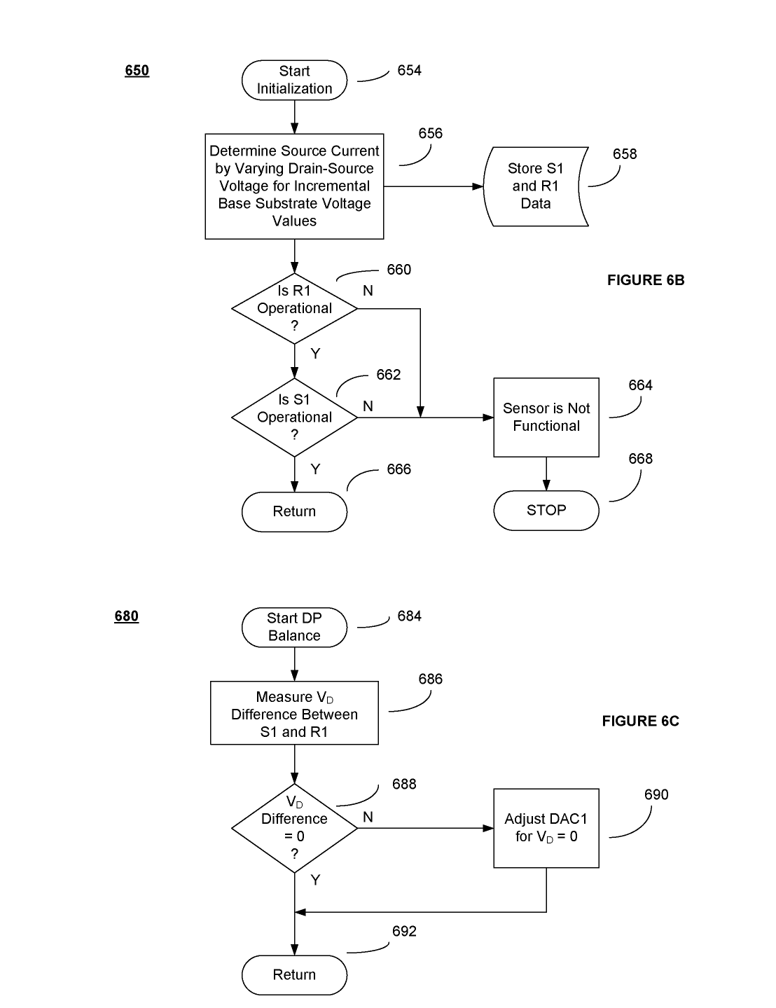

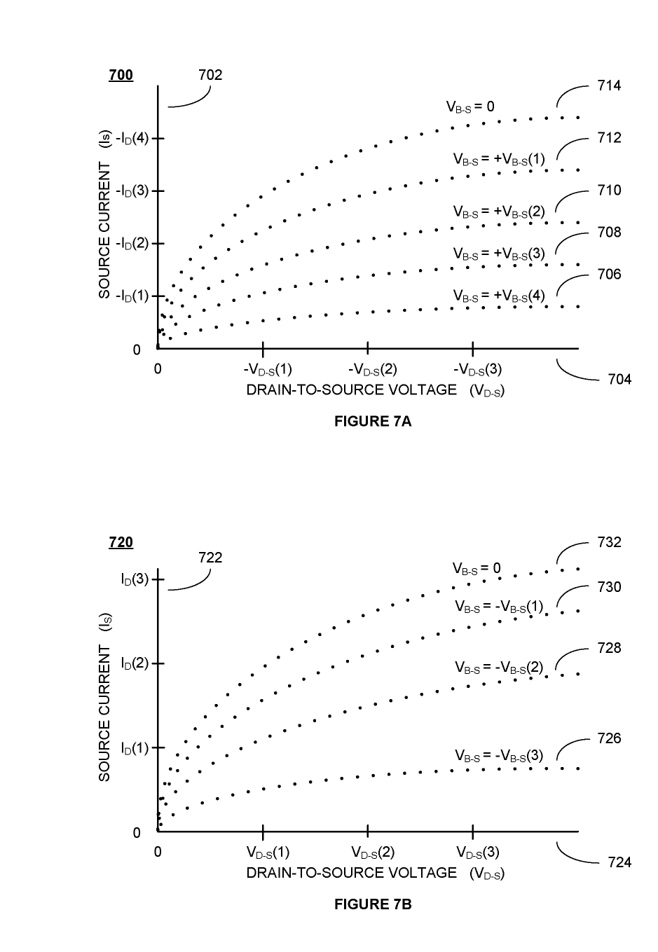

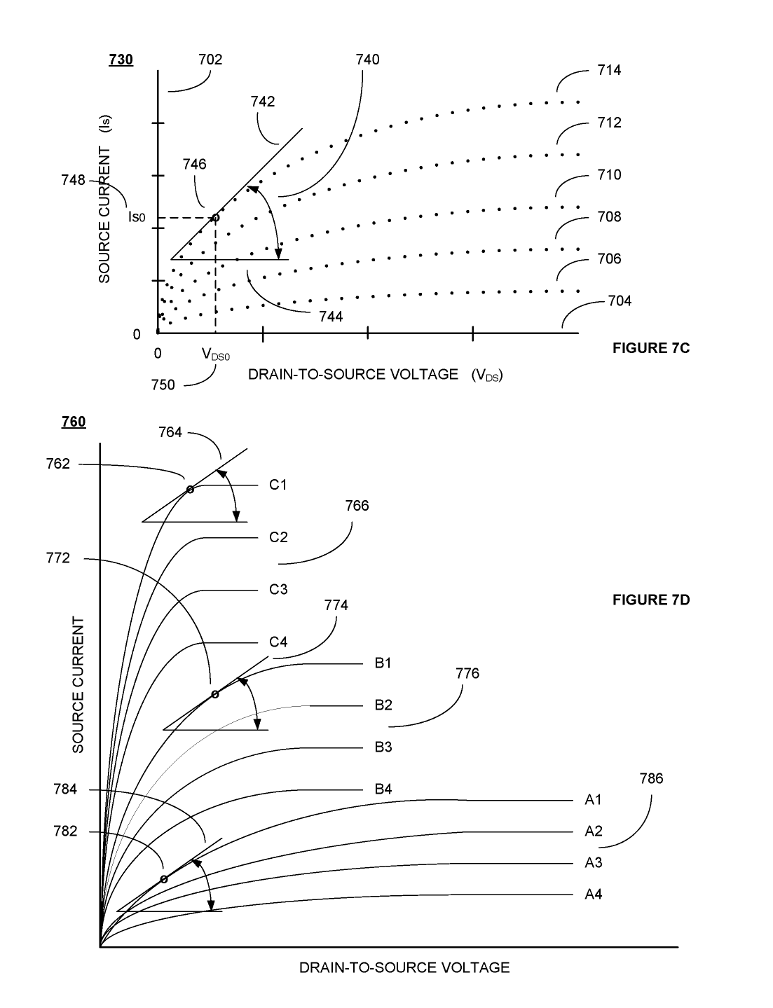

Turning to FIGS. 6A-6C, FIGS. 6A depicts the steps of a sensor optimization algorithm 600 executing in a digital signal processor for controlling the differential pair of field effect transistors as shown in FIGS. 5A and 5B above. The sensor optimization algorithm is started 610 manually by the operator. An initialization routine 612, described in more detail below in FIG. 6B below, results in the storing of parametric data 614, illustrated in FIG. 7A and FIG. 7B, for the sensor field effect transistor S1 and the reference field effect transistor R1 derived from measurements performed on the differential pair by the algorithms in the digital signal processor using DAC4, DAC5, DAC6, B3, B4 and A9 (582, 574, 594, 578, 576, 586) shown in FIG. 5B. Based on the data 614 gathered during execution of the initialization routine 612 and illustrated in FIG. 7A and FIG. 7B, optimized parameter values for the sensor field effect transistor S1 are determined 616, and the optimal operating point of the sensor field effect transistor S1 is identified. The output voltage of DAC5 and DAC6 (574, 594 in FIG. 5B) are adjusted 618 to provide source current for the sensor field effect transistor S1 and the reference field effect transistor R1, and drain voltage to the common substrate base of the differential pair that conforms to optimized parameter values. The differential pair is then balanced 622, as described in further detail in FIG. 6C described below. The actual position of the sensor field effect transistor S1 operating point is determined 626 and compared to the computed optimal operating point 628. If the S1 operating point is optimal, the processing of recognition element reactions with targets is conducted 630, and any reaction data is stored 632. This reaction data are used for analyzing and final decision-making about chemical and biochemical processes on the surface of the S1 sensor. If a STOP command is not received from an operator 636, and S1 is optimal 642, the target recognition process continues 630. If S1 is found to be not optimal the initialization step is repeated 612. Returning to step 628, if the determined operating point is significantly different from the computed operating point 628, the optimization process of the differential pair of field effect transistors is conducted. If the S1 operating point is not optimal 628, it is determined if the source current source is optimal 634. If the source current is not optimal 634, the current is adjusted via DAC6 640 (594 in FIG. 5B), the differential pair is balanced according to FIG. 6C below 644, and it is then determined if the drain voltage is optimal 624. If, in step 634, it was determined that the current source current is optimal, it is also then determined if the drain voltage is optimal 624. If the S1 drain voltage is not optimal 624, DAC5 (574 in FIG. 5B) is adjusted 620 and the differential pair is balanced 622 according to FIG. 6C below. If the S1 drain voltage is optimal 624, the differential pair is also balanced 622

FIG. 6B depicts the steps required 650 for the initialization step in FIG. 6A above. The initialization process is to control and confirm the functionality of differential pair of field effect transistors. Upon initialization 654, transistor curve data and work point of differential pair S1 and R1 are collected 656 and stored 658. The drain-to-source voltage data of the differential pair (514 in FIG. 5B) is determined by varying the source current via DAC6 (594 in FIG. 5B) for incremental values of base substrate voltage 656 via DAC5 (574 in FIG. 5B). The base voltage, source voltage and current source output voltage are simultaneously measured (576, 578, 586 in FIG. 5B) Sampled data values of the drain-to-source voltage and source current for the sensor field effect transistor S1 and reference field effect transistor R1 are stored 658. These sampled data values are represented by the data points plotted in FIG. 7A and FIG. 7B. From this data, it is determined if R1 is operational 660. If either R1 is not operational 660 or S1 is not operational 662, the sensor is not functional 664 and further processing is stopped. 668. If both R1 is operational 660 and S1 is operational 662, control is returned to step 616 in FIG. 6A.

FIG. 6C depicts the steps required to balance the differential pair of field effect transistors S1 and R1 680. When started 684, the difference between the drain voltages of S1 and R1 are measured 686 via Bi and B2 (554, 558) in FIG. 5B. If the difference is zero 688, control is returned to the requesting step 692 in FIG. 6A. If the difference is not zero 688, DAC1 (546 in FIG. 5B) is adjusted so that the difference in drain voltages of R1 and S1 is zero 690, and control is returned to the requesting step 692 in FIG. 6A.

Turning to FIG. 7A, FIG. 7A depicts typical plotted parametric data 700 obtained in step 656 of FIG. 6B above from a differential pair of p-channel depletion mode field effect transistors by a digital signal processor. The data points represent values of source current 710 as the drain to source voltage 720 is varied while holding constant incremental values of base-source voltage 730, 732, 734, 736, 738 for the sensor field effect transistor and the reference field effect transistors. Each data point on the graph represents a value of source current for a given value of drain-source voltage and a given value of base-source voltage.

Turning to FIG. 7B, FIG. 7B depicts typical plotted parametric data 750 obtained in step 656 of FIG. 6B above from a differential pair of n-channel depletion mode field effect transistors by a digital signal processor. The data points represent values of source current 760 as the drain to source voltage 770 is varied while holding constant incremental values of base-source voltage 780, 782, 784, 786 for the sensor field effect transistor and the reference field effect transistors. Each data point on the graph represents a value of source current for a given value of drain-source voltage and a given value of base-source voltage.

Turning to FIG. 7C, FIG. 7C depicts an optimization method using the plotted static parametric data of FIG. 7A, shown as a reference transistor. An optimum operating point 746 of the sensor field effect transistor of a differential pair of field effect transistors is determined by choosing a line 742 that is tangent to a maximum response curve 714 at between a 40° and 45° angle 740 to the horizontal 744. The 40° to 45° angle 740 is chosen to give a maximum gain and dynamic range of the differential pair analog circuitry without saturating the analog circuitry, while maintaining an acceptably low noise level from the analog circuitry. As shown in FIG. 7C, an optimized operating point 746 gives a source current of Iso 748 and a drain-to-source voltage of V_{DSO} 750.

Turning to FIG. 7D, FIG. 7D depicts an optimization method using the static plotted data and method of FIG. 7C, shown as a family of curves A1-A4 786 without chemistry applied, a family of curves B1-B4 776 after chemistry and biology are applied, and a family of response curves C1-C4 766 after an environmental change in acidity (Ph). The optimized operating points 782, 772, 762 are determined by finding a point where a line 784, 774, 764 at an angle between 40° and 45° to the horizontal is tangent to a maximum response curve in a family of response curves 786, 776, 766, respectively. As these families of curves illustrate, the shape of the response curves are changing dynamically as environmental and operating conditions change. In order to achieve sufficient gain, response times and stability of the analog circuitry, this dynamic condition must be dynamically stabilized by the optimizing operation of the digital signal processor.

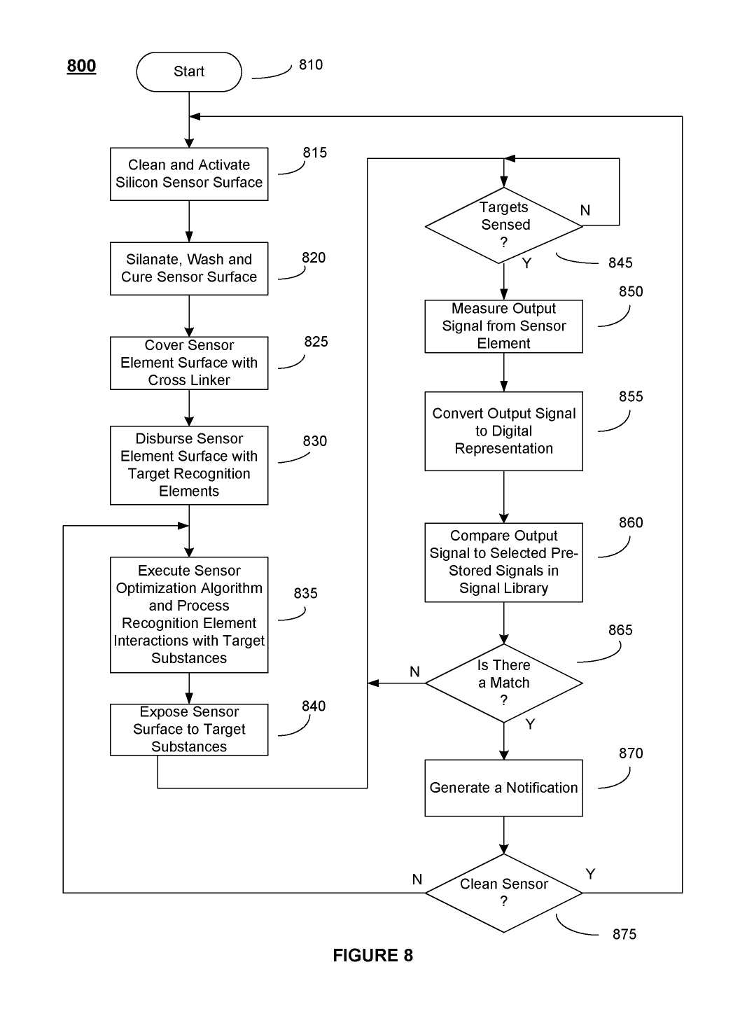

Turning to FIG. 8, FIG. 8 depicts process steps for implementing an operational embodiment of the present invention 800. The process 800 is started 810 by cleaning and activating the surface of the sensor 815. This may be accomplished by mechanical chiseling, laser cleaning, chemically cleaning or thermally cleaning, so as not to affect the effectiveness of the sensor elements. Thermally cleaning the sensor elements comprises raising the temperature of the sensor surface using the sensor heating element (564 in FIG. 5C) to a cleaning temperature in excess of the normal operating temperature, typically between 35° Celsius and 80° Celsius. The sensor surface is then treated with a silane solution, washed and cured 820. The surface of the sensor element is then treated with cross-linkers 825 to provide an appropriate orientation to the target recognition elements. The surface of the sensor element is then coated with selected target recognition elements 830 capable of uniquely sensing specific target types, such as an H5 antibody and an N1 antibody and may be suspended in a gel. The sensor optimization algorithm described above in FIG. 6A is executed 835 and the system is then deployed to expose the sensor element to targets 840. The system then looks for an output signature signal from the sensor element 845. If an output signature signal is detected, it is measured 850 and converted to a digital representation 855. The output signal may be a measurement of conductance, voltage, current, capacitance and resistance that is converted to a digital representation. The digital representation may be a time-varying signal having an amplitude and a plurality of frequencies. The output signature signal is then compared to a library of pre-stored signature signals 860 to determine if there exists a match to a known target or target type 860. If no match exists 865, the system returns to sensing an output signal from the sensor element 845. If a match is found between the output signature signal and one or more pre-stored signature signals in the library 865, an event log and notification is generated and sent to appropriate authorities 870. Based on either pre-selected automatic criteria or user selected criteria, an alert may be sent 870. It must then be determined if it is necessary to clean the sensor surface 875. If the sensor surface requires cleaning 875, the process then returns to the beginning for cleaning the sensor surface 815. If the sensor surface does not require cleaning 875, the system returns to executing the sensor operating algorithm 835 and exposing the sensor elements to harmful antigens 840. Operation may be continuous and event detection may occur in real-time.

The processes of attaching recognition elements to a sensor and the binding or interaction that occurs when a recognition element combines with a target type are well-known in the art. The recognition elements are attached to the sensor surface, usually by a covalent attachment method (although in other embodiments non-covalent attachment methods may be used).

The process of binding between a recognition element that is an antibody and a target type that is an antigen will be described and is for illustration purposes. It should be understood that the present invention is not limited to antibodies and proteins but includes all the types of recognition elements and target types defined and listed above.

The process of binding is well understood at the conceptual level though the process is complex at the atomic level. Several recent studies have mapped the structural changes, kinetics and thermodynamics that occur in specific recognition element and target interactions (James & Tawfik, 2005; Grubor et al. 2005; Xavier et al. 1997; 1998, 1999; Jackson 1998; Sinha, et al. 2002). Conceptually the interaction involves numerous dipole-dipole interactions resulting from the specific amino-acids mostly within a region of the antibody known as the hypervariable region and with specific features or amino-acids within the antigen (epitope-region). The antibody and antigen may each be considered as complex dipoles with their own electric fields, which result from negative and positive charged regions. For an antibody and antigen, the interaction or binding process involves forming multiple non-covalent bonds and involves various electrostatic attractive and repulsive forces such as hydrogen-bonds, electrostatic forces, Van der Waals and hydrophobic forces between the individual dipole-regions. Though some individual bonds may be weak, the cumulative effect may be very strong. This overall strength of the interaction is known as its affinity. The strength of bonding is a function of the number, separation and nature of these individual bonds. Since these bonds are non-covalent, binding is reversible.

The first steps of interaction involve long-distance attraction of oppositely charged dipoles which serve to bring potential binding partners into relatively close proximity. If it is assumed the antibody is covalently attached to the surface, this will mainly involve attraction of the antigen towards the antibody. However, it is recognized that protein molecules (and antigens) are inherently flexible, and that a certain degree of distortion of both the antibody and antigen molecule will occur, and this may alter the distribution of charge on these molecules. As two well-matched molecules, that when a recognition element and a target that have a strong binding affinity, approach each other, the generalized dipole-dipole attraction will be superseded by more specific interactions (including but not limited to charge-based attraction, repulsion and neutralization) between individual amino-acids or groups of amino-acids within the antibody and antigen and may involve further protein conformational changes, particularly around the specific amino-acids involved in the interaction. Known as induced-fit, this conformational rearrangement process is an important feature of interaction specificity, and results in a complex with a favorable thermodynamic state, and involves both backbone and side-chain rearrangements and the formation of specific hydrogen-bonds. Even small changes in the charge distribution at the interaction site during the interaction process can result in quite large changes in interaction strength which translate into differences in bonding strength and specificity. These processes involve changes in enthalpy such as formation or dissolution of bonds (including but not limited to hydrogen bonds, Van der Waals, salt-bridges and the like) or the displacement of water, as well as changes in overall entropy (binding favored by an increase in entropy). As the interaction proceeds, various changes in charge distribution may occur, which will result in changes in the electrical field of the individual entities. These changes in charge, especially those close to the sensor surface are registered by the sensor device and recorded.

Turning to FIGS. 9A-9D, FIGS. 9A-9D show typical responses 900 from a differential pair of field effect transistors with binding and without binding of a target recognition element and a target. If the sensor gate area shown in FIG. 1A was coated with H5 target recognition elements and exposed to an H1 target type, a typical response 910 from the sensor differential pair, normalized by differential amplifier A6 556 in FIG. 5B, shown in FIG. 9A may result. FIG. 9A shows a negative signature response characteristic 910 indicating that an H5 target type was not detected. If the sensor gate area shown in FIG. 1A was coated with H5 target recognition elements and exposed to an H5 target type, a typical response 920 from the sensor differential pair, normalized by differential amplifier A6 556 in FIG. 5B, shown in FIG. 9B may result. FIG. 9B shows a positive signature response characteristic 920 indicating that an H5 target type was detected. If the sensor element shown in FIG. 1A was coated with N1 target recognition elements and exposed to an N5 target type, a typical response 930 from the sensor differential pair, normalized by differential amplifier A6 556 in FIG. 5B, shown in FIG. 9C may result. FIG. 9C shows a negative signature response characteristic 930 indicating that an N1 target type was not detected. If the sensor element shown in FIG. 1A was coated with N1 target recognition elements and exposed to an N1 target type, a typical response 940 from the sensor differential pair, normalized by differential amplifier A6 556 in FIG. 5B, shown in FIG. 9D may result. FIG. 9D shows a positive signature response characteristic 940 indicating that an N1 target type was detected.

FIG. 10A illustrates a two by two sensor array 1010 in a typical system configuration 1000, where the elements 1020, 1022, 1030, 1032 in the array may be selected from one of the embodiments of the sensor elements shown in FIG. 2 through FIG. 9 above or may be some other type of sensor element such as a single electron transistor. A sample of the output of the sensor elements 1020, 1022, 1030, 1032 is sent a digital signal processor 1040 for conversion to a digital equivalent signal sample. A plurality of digital equivalent signal samples from each sensor element in the sensor array 1010 are combined to form a digital signature signal for each element in the array 1010. This process of digitizing outputs from the sensors and reconstructing a digital signature signal is well-known to those skilled in the relevant art of digital signal processing. The embodiment in FIG. 10A shows one digital signal processor 1040 connected to each individual sensor element 1020, 1022, 1030, 1032. Multiple embodiments with varying combinations of sensor elements and number of digital signal processor are possible. Other embodiments may include more than one digital signal processor, for example, one digital signal processor may be present and connected to one sensor element, a second digital signal processor may be present and connected to a second sensor element, and so forth. Likewise, alternative embodiments of the sensor array may include any combinations of rows and columns of sensor elements. The one or more digital signal processors, then may compare each digitized sensor output signature signal with a library of pre-stored signature signals representing known targets that may bind with a recognition element (see FIG. 8). In this manner, any target that binds with a recognition element and whose signal matches any one of the stored signals is sensed and processed in real-time.

The digital signal processor 1040 may process the signals using several alternate process embodiments. One embodiment is a process to sequentially compare each of a time domain digitized sensor signature signal with each of the pre-stored time domain signature signal in a signal library using cross-correlation techniques to determine a match. Another process embodiment is to sequentially convert each received digitized sensor signature signal to a frequency spectrum and then sequentially compare each of the frequency domain digitized sensor signature signals with each of the pre-stored frequency domain signature signals in the signal library using cross-correlation techniques to determine a match.

An example of how recognition elements rows 1070, 1072, 1074, 1076 and columns 1080, 1084, 1086 may be distributed on a four by four sensor array 1050 is shown in FIG. 10B. As a first example, assume that the sensor element located at column 1 1080 row 1 1070 of the sensor array 1050 is coated with an H5 antibody (ligand). If the sensor array 1050 were exposed to an H1 antigen, a response from the sensor located at column 1 1080 row 1 1070 shown in FIG. 9A would result. FIG. 9A shows a negative signature response characteristic indicating that an H5 antigen was not detected. If the sensor array 1050 were exposed to an H5 antigen, a response from the sensor located at column 1 1080 row 1 1070 shown in FIG. 9B would result. FIG. 9B shows a positive signature response characteristic indicating that an H5 antigen was detected,

As a second example, assume that the sensor element located at column 4 1086 row 3 1074 of the sensor array 1050 is coated with an NI antibody. If the sensor array 1050 were exposed to an N5 antigen, a response from the sensor element located at column 4 1086 row 10 1074 shown in FIG. 9C would result. FIG. 9C shows a negative signature response characteristic indicating that an N1 antigen was not detected. If the sensor array 1050 were exposed to an N1 antigen, a response from the sensor element located at column 4 1086 row 10 1074 shown in FIG. 9D would result. FIG. 9D shows a positive signature response characteristic indicating that an N1 antigen was detected. It should be noted, for example, that simultaneous positive responses from a sensor element coated with H5 antibodies and a sensor element coated with N1 antibodies would indicate a presence of the H5N1 avian flu virus.

It should also be noted that although the sensor arrays 1010, 1050 shown in FIGS. 10A and 10B are a two by two (2 by 2) and four by four (4 by 4) square array, respectively, an array according to the present invention may take on numerous elements and array configurations. For example, an array may be a square array, a rectangular array, a three dimensional array, a circular array and the like. The array may also include any number of array elements. It should also be noted that the examples used are illustrative only and not limited to the specific detections described. The detections illustrated in FIGS. 9A through 9D and in FIGS. 10A and 10B may encompass detecting the presence or absence of any type of target that is capable of interacting with a recognition element and is not limited to the examples cited herein.

Although the present invention has been described in detail with reference to certain preferred embodiments, it should be apparent that modifications and adaptations to those embodiments might occur to persons skilled in the art without departing from the spirit and scope of the present invention.

1. A sensor method for detecting one or more target substances, comprising:
providing a differential pair of field effect transistors comprising:
a reference field effect transistor having a reference gate area, wherein the reference gate area is covered to prevent contact of the reference gate area with the one or more target substances; and
a sensor field effect transistor having a sensor channel and a sensor gate area, wherein the sensor gate area is exposed, and wherein the sensor gate area is provided with one or more target recognition element types to react with the one or more target substances;
wherein the reference field effect transistor and the sensor field effect transistor have a common substrate and a common source connection, the differential pair of field effect transistors operably connected to a common current source and a digital signal processor;
obtaining a differential output signature signal from:
a common mode signal obtained from the reference field effect transistor, and
a sensor output signature signal obtained from the sensor field effect transistor;
balancing the differential output signal signature of the differential pair of field effect transistors by controlling, at the digital signal processor, the common current source;
monitoring the differential output signal signature of the differential pair of field effect transistors to detect the one or more target substances; and
notifying a user of the detection.

2. A sensor method for detecting one or more target substances, comprising:
monitoring parameters of the differential pair of field effect transistors, the differential pair of field effect transistors comprising:
a reference field effect transistor having a reference gate area, wherein the reference gate area is covered to prevent contact of the reference gate area with the one or more target substances; and
a sensor field effect transistor having a sensor channel and a sensor gate area, wherein the sensor gate area is exposed, and wherein the sensor gate area is provided with one or more target recognition element types to react with the one or more target substances;
wherein the reference field effect transistor and the sensor field effect transistor have a common substrate and a common source connection;
controlling operating characteristics of the differential pair of field effect transistors by a digital signal processor to an optimum operating range for signal sensing;
obtaining a differential output signature signal from:
a common mode signal obtained from the reference field effect transistor; and
a sensor output signature signal obtained from the sensor field effect transistor; and
monitoring the differential output signal signature of the differential pair of field effect transistors to detect the one or more target substances.

3. (canceled)

4. The sensor method of claim 1, wherein the differential pair of field effect transistors are in close proximity to one another on the common substrate for minimizing differences in environmental and electrical influences between both field effect transistors in the differential pair.

5. The sensor method of claim 1, wherein the step of balancing further comprises controlling the operating characteristics of the differential pair by the digital signal processor by controlling a common substrate voltage and a quiescent drain voltage of the reference field effect transistor based on the optimization algorithms.

6. The sensor method of claim 1, further comprising providing a temperature sensor and a heating element on a single silicon substrate with the differential pair of field effect transistors.

7. The sensor method of claim 6, further comprising reading the temperature sensor signal and controlling a temperature of the single silicon substrate by controlling a signal to the heating element by the digital signal processor.

8. The sensor method of claim 7, further comprising the steps of self-cleaning the sensor gate area and maintaining a stable temperature during normal sensing operations by controlling the temperature sensor and the heating means by the digital signal processor.

9. The sensor method of claim 1, wherein the one or more target recognition element types comprises a first target recognition element type for reacting with only a first target types for producing a time-varying signature output signal from the sensor field effect transistor and the reference field effect transistor of the differential pair, the time-varying signature output signal for identifying and distinguishing the reaction of the first target recognition element type with the first target type from other reactions by the characteristics of the time-varying signature output signal.

10. The sensor method of claim 9, wherein the time-varying signature output signal comprises an amplitude and a plurality of frequencies.

11. The sensor method of claim 10, further comprising providing a plurality of stored time-varying signature output signals in a memory of the digital signal processor, comparing the plurality of stored time-varying signal output signals with the time-varying signature output signal and identifying the first target type.

12. The sensor method of claim 1, wherein the one or more target recognition element types comprise a first target recognition element type and a second target recognition element types and the one or more target substances comprise a first target type and a second target type, the method further comprising reacting the first target recognition element type disbursed over the sensor gate area with the first target type and reacting the second target recognition element type disbursed over the sensor gate area with the second target type for producing a time-varying, superimposed first and second output signature signal from the sensor field effect transistor and reference field effect transistors of the differential pair, the first and second output signature signals each having characteristics that identify and distinguish the first output signature signal from the second output signature signal and the first and second output signature signal from other reactions.

13. The sensor method of claim 12, further comprising including in the digital signal processor a memory having a plurality of stored output signature signals for comparing with the measured superimposed first and second output signature signals and identifying the first and second target types.

14. The sensor method of claim 1, wherein the one or more target recognition element types is selected from the group consisting of proteins, nucleic acids, inorganic molecules and organic molecules.

15. The sensor method of claim 1, wherein the one or more target recognition element types is selected from the group consisting of antibodies, antibody fragments, oligonucleotides, DNA, RNA, aptamers, enzymes, cell fragments receptors, bacteria, bacterial fragments, viruses and viral fragments.

16. The sensor method of claim 1, wherein the one or more target recognition element types is selected from the group consisting of molecules, compounds, complexes, nucleic acids, proteins, viruses, bacteria, bacterial fragments, cells, cell fragments, inorganic molecules and organic molecules.

17. The sensor method of claim 7, further comprising using the heating element to heat the sensor gate area to a temperature of between about 35° Celsius and about 80° Celsius to self-clean the sensor gate to allow for reuse of the sensor system.

18. A method of using a sensor array comprising two or more sensors for detecting one or more target substances, comprising.
providing a first differential pair of field effect transistors of a first sensor of the sensor array comprising:
a first reference field effect transistor having a reference gate area, wherein the reference gate area is covered to prevent contact of the reference gate area with the one or more tare substances; and
a first sensor field effect transistor having a sensor channel and a sensor gate area, wherein the sensor gate area is exposed, and wherein the sensor gate area is provided with one or more target recognition element types to react with the one or more target substances;
wherein the first reference field effect transistor and the first sensor field effect transistor have a common substrate and a common source connection;
obtaining a first differential output signature signal from:
a common mode signal obtained from the first reference field effect transistor; and
a sensor output signature signal obtained from the first sensor field effect transistor;
monitoring the first differential output signal signature of the first differential pair of field effect transistors to detect the one or more target substances;
providing a second differential pair of field effect transistors of a second sensor of the sensor array comprising:
a second reference field effect transistor having a reference gate area, wherein the reference gate area is covered to prevent contact of the reference gate area with the one or more target substances; and
a second sensor field effect transistor having a sensor channel and a sensor gate area, wherein the sensor gate area is exposed, and wherein the sensor gate area is provided with one or more target recognition element types to react with the one or more target substances;
wherein the second reference field effect transistor and the second sensor field effect transistor have a common substrate and a common source connection;
obtaining a second differential output signature signal from:
a common mode signal obtained from the second reference field effect transistor, and
a sensor output signature signal obtained from the second sensor field effect transistor; and
monitoring the second differential output signal signature of the second differential pair of field effect transistors to detect the one or more target substances.

19. The sensor method of claim 18, further comprising detecting a presence of two or more target substances using two more sensors within the sensor array.

20. The sensor method of claim 19, further comprising detecting the presence of a first target type using the first sensor within the sensor array and detecting the presence of a second target type using the second sensor within the sensor array.

21. The sensor method of claim 1, wherein the reference field effect transistor is located adjacent to the sensor field effect transistor on the common substrate without any other intervening field effect transistor located between the reference field effect transistor and the sensor field effect transistor.
